(19) United States
(12) Patent Application Publication
(10) Pub. No.: US 2024/0120705 A1
(43) Pub. Date: Apr. 11, 2024

(54) ISOLATING HEAT SPREADER

(71) Applicant: International Business Machines Corporation, Armonk, NY (US)

(72) Inventors: Keiji Matsumoto, Yokohama-shi (JP); Mukta Ghate Farooq, HOPEWELL JCT, NY (US); John Knickerbocker, Monroe, NY (US)

(21) Appl. No.: 17/962,434

(22) Filed: Oct. 7, 2022

(51) Int. Cl. H01S 5/024; H01L 23/367; H01L 23/373

(52) U.S. Cl. CPC H01S 5/02469; H01L 23/367; H01L 23/373

(57) ABSTRACT

A heat spreader apparatus includes a first portion; a second portion; and a connecting portion between the first and second portions, with high-conductivity axes and a low-conductivity axis, the low-conductivity axis being directed between the first and second portions. In one or more embodiments, the first, second, and connecting portions are thermally anisotropic blocks, and the apparatus forms a rectangular prism.

### BACKGROUND

The present invention relates to the electrical, electronic, and computer arts, and more specifically, to cooling combined electro-optical devices.

Optical devices, such as VESELs (VErtical-cavity Surface Emitting Lasers, also known as VCSELs), are temperature-sensitive, because when the temperature changes, the wavelength of emitted light changes. When a high-heat-dissipating chip (e.g., CPU or GPU) co-exists with a VCSEL or another optical element (active device or passive component), the high-heat-dissipating chip's maximum chip temperature needs to be managed (typically as low as possible) and the temperature of the optical chip or component may need to be managed to a controlled temperature range.

### SUMMARY

Principles of the invention provide techniques for an isolating heat spreader. In one aspect, an exemplary apparatus includes a substrate; a processing unit that is mounted to the substrate; an optical element that is mounted to the substrate with the processing unit; and a heat spreader that is attached to surfaces of the chip and of the optical element, opposite the substrate. The heat spreader includes: a first thermally anisotropic portion that is adjacent to the chip, with high-conductivity axes and a low-conductivity axis, one of the high-conductivity axes being directed away from the chip; a second thermally anisotropic portion that is adjacent to the optical element, with high-conductivity axes and a low-conductivity axis, one of the high-conductivity axes being directed away from the optical element; and a connecting thermally anisotropic portion that is between the first and second thermally anisotropic portions, with high-conductivity axes and a low-conductivity axis, the low-conductivity axis being directed between the first and second thermally anisotropic portions. The connecting thermally anisotropic portion effectively thermally isolates the first thermally anisotropic portion from the second thermally anisotropic portion.

According to another aspect, an exemplary heat spreader apparatus includes a first portion; a second portion; and a connecting portion between the first and second portions, with high-conductivity axes and a low-conductivity axis, the low-conductivity axis being directed between the first and second portions. The high-conductivity axes have a thermal conductivity at least 100 times a thermal conductivity of the low-conductivity axis.

According to another aspect, an exemplary apparatus includes a substrate; processing unit that is mounted to the substrate; an optical element that is mounted to the substrate with the processing unit; and a heat spreader that is attached to surfaces of the chip and of the optical element, opposite the substrate, wherein the heat spreader comprises: a backplane that defines first, second, and third slots; a first highly thermally conductive block fit into the first slot adjacent to the chip; a second highly thermally conductive block fit into the second slot adjacent to the optical element; and an interposing block fit into the third slot between the chip and the optical element.

In view of the foregoing, techniques of the present invention can provide substantial beneficial technical effects. For example, one or more embodiments provide one or more of:

A high-heat-dissipating chip (e.g., a processor) and a temperature-sensitive optical element that are mounted to the same substrate and heat spreader without adverse thermal effects on operation of the optical element.

A small-form-factor-package that enhances the benefit of co-existence of a high-heat-dissipating chip and a temperature-sensitive optical element by minimizing the distance between these two devices.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 and FIG. 2 depict, in schematics, an exemplary composite graphite heat spreader, according to exemplary embodiments.

FIG. 3 and FIG. 4 depict mechanical details of an exemplary embodiment of the composite graphite heat spreader that is shown schematically in FIG. 1 and FIG. 2.

FIG. 5 depicts a top view finite element analysis of temperatures in the heat spreader that is shown in FIG. 1 through FIG. 4.

FIG. 6 depicts a bottom view finite element analysis of temperatures in a substrate to which a chip and an optical element are mounted, as shown in FIG. 4.

FIG. 7 depicts, in a schematic, a heat spreader that has slots, according to exemplary embodiments.

### DETAILED DESCRIPTION

A graphite heat spreader is a promising candidate for reducing the overall temperature of a high-heat-dissipating (e.g., greater than 25 W/cm², or, in some embodiments, greater than 45 W/cm² heat dissipation) chip (e.g., a CPU or GPU) and an optical element (e.g., an active device such as a VCSEL, or a passive component such as a splitter) combination, because the thermal conductivity of graphite is anisotropic: in the x and y directions (in the graphite crystal plane), thermal conductivity is as high as 1500 W/m-K; in the z direction (orthogonal to the crystal plane), thermal conductivity is about 6 W/m-K. Thus, an optimally thin graphite heat spreader could substantially reduce the temperature of a high-heat-dissipating chip. When a graphite heat spreader is used for an optical element and a high-heat-dissipating chip, however, there is a concern that thermal coupling between the optical element and the high-heat-dissipating chip may occur. The temperature of an optical element may be affected by heat from the high-heat dissipating chip, which could cause unstable operation of the optical element. One or more embodiments advantageously reduce or even avoid this problem.

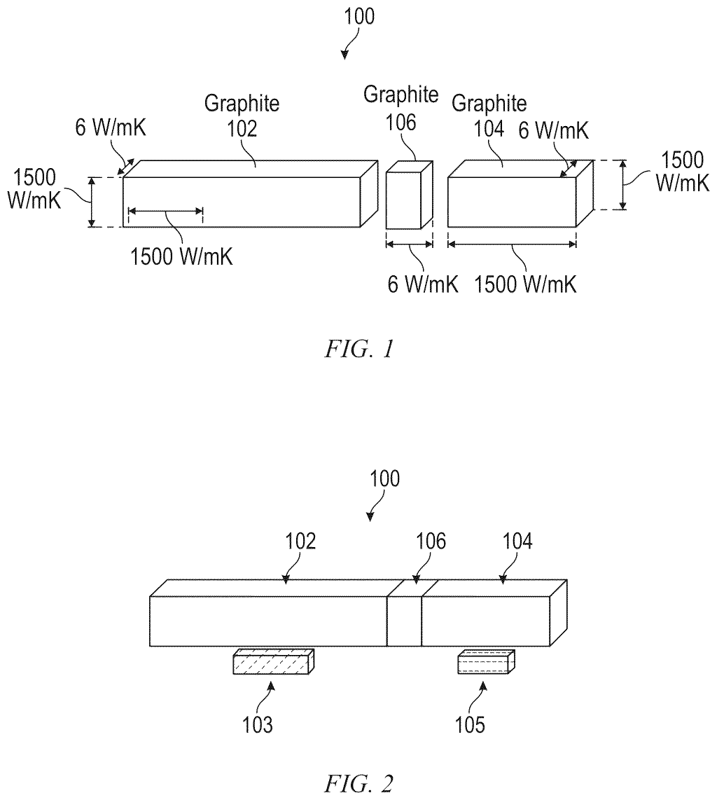

One or more embodiments advantageously mitigate heat spread from a high-heat-dissipating chip through a graphite heat spreader to an optical element by making the graphite heat spreader a composite structure with segments or portions that have the low-conductivity (e.g., 6 W/m-K) axis arranged in different directions. Providing the heat spreader as a single composite component of uniform thickness obviates a problem of trying to make a cold plate conform to multiple separate spaced-apart heat spreaders. Accordingly, FIG. 1 and FIG. 2 depict, in schematics, an exemplary composite graphite heat spreader 100. The composite graphite heat spreader 100 includes a first portion 102 that is above a high-heat-diffusion chip 103 (e.g., a processing unit such as a CPU or GPU), a second portion 104 that is above an optical element 105 (e.g., a VCSEL), and a connecting portion 106 that mechanically joins the first and second portions 102, 104. For ease of assembly, in one or more embodiments the first, second, and connecting portions all have the same vertical thickness. The connecting portion 106 has the low-conductivity axis oriented from the first portion 102 to the second portion 104 so that the connecting portion 106 effectively thermally isolates the first portion 102 from the second portion 104. This obviates the potential problem with heat spreading from the high-heat-dissipating chip 103 to the optical element 105 via the heat spreader 100.

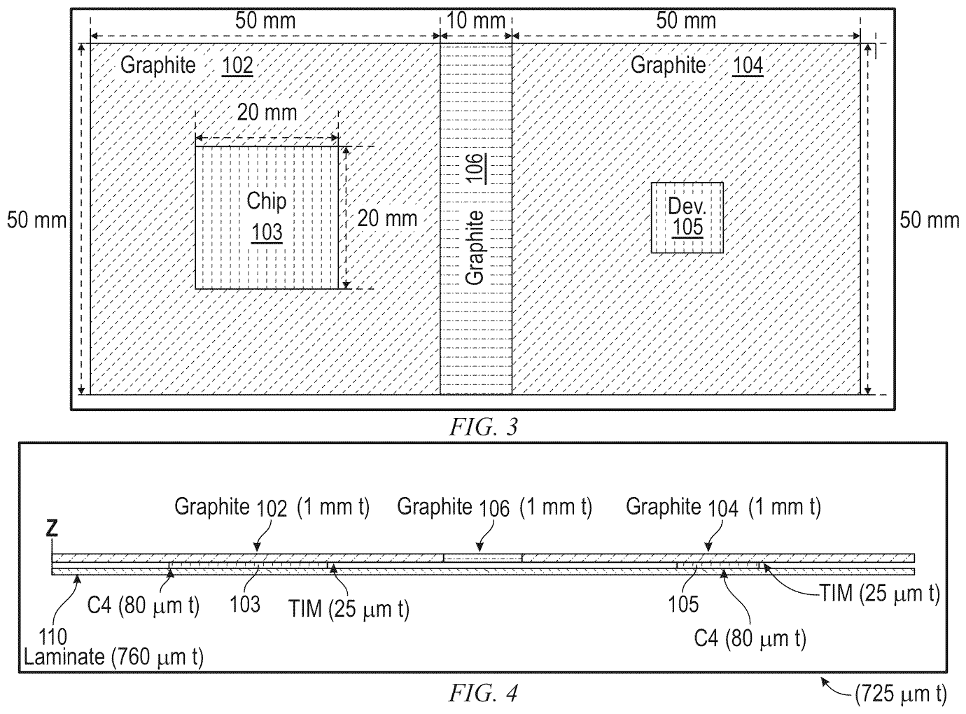

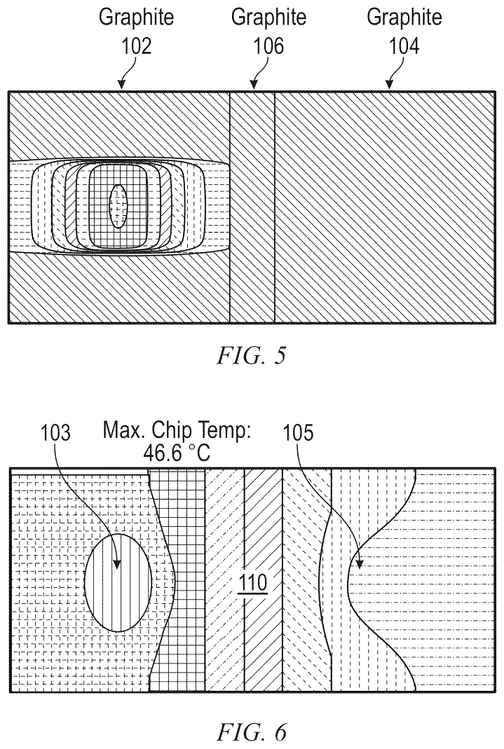

FIG. 3 and FIG. 4 depict mechanical details of an exemplary embodiment of the composite graphite heat spreader 100. Note the controlled collapse chip connections C4, the thermal interface material TIM, and the substrate 110 to which the chip 103 and the optical element 105 are mounted. The dimensions in FIGS. 3 and 4 are exemplary and non-limiting. In one or more embodiments, the substrate 110 includes a laminate structure, e.g., a printed circuit board.

FIG. 5 depicts a top view finite element analysis of temperatures in the heat spreader 100. FIG. 6 depicts a bottom view finite element analysis of temperatures in the substrate 110. The ordinary skilled worker will appreciate from the views of FIG. 5 and FIG. 6 that the connecting portion 106 of the composite graphite heat spreader 100 effectively thermally isolates the first portion 102 from the second portion 104, and that for at least this reason, the second portion 104 is effective to cool the optical element 105 down to near-ambient temperature. Indeed, the second portion 104 also cools the substrate 110 via the optical element 105, i.e. heat flows from the substrate through the optical element to the second graphite portion.

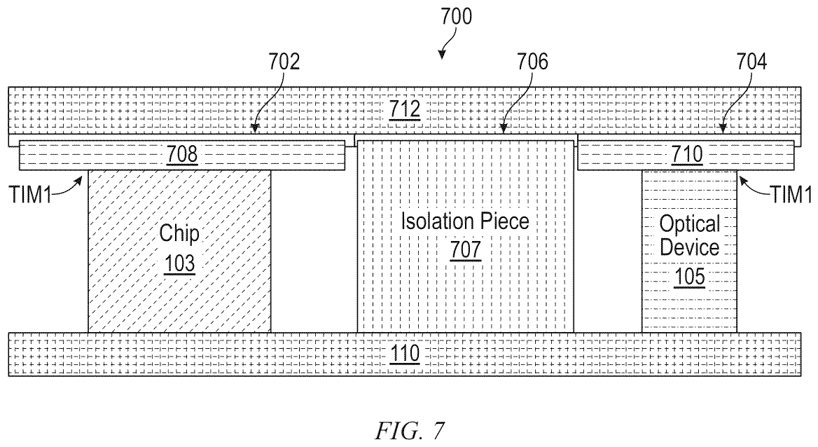

Other exemplary embodiments provide a heat spreader with slots. FIG. 7 depicts, in a schematic, a heat spreader 700 that has slots 702, 704, 706. First slot 702 receives a high-heat-dissipating chip 103, second slot 704 receives an optical element 105, and the connecting slot 706 receives an isolating block 707. As one example, graphite block 708 joins the high-heat-dissipating chip 103 to the slot 702, while graphite block 710 joins the optical element 105 to the slot 704. Any high thermal conductivity materials (such as above 50 W/m-K) can be used as 708 and 710. A cold plate 712 is affixed to the heat spreader 700 opposite the chip 103 and the optical element 105. In one or more embodiments, the heat spreader 700, slots 702, 704, 706, and the cold plate 712 are made of one or more relatively-high-conductivity material(s) that have thermal conductivity in excess of about 50 W/m-K, e.g., a metal such as copper or aluminum or a ceramic such as silicon carbide or aluminum nitride. In one or more embodiments, the isolating block 707 is made of a relatively-low-conductivity material that has thermal conductivity of less than about 1 W/m-K, e.g., an organic engineering polymer such as epoxy or acrylic, acrylonitrile-butadiene-styrene (ABS), or polycarbonate (PC). The isolating block 707 blocks radiative and convective heat transfer from the high-heat-dissipating chip 103 to the optical element 105. Note the thermal interface material TIM1.

Generally, where thermal interface material is used, it may be a metal foil (e.g., Indium), a thermal grease, or similar material that conforms to surfaces and provides good conductivity between adjacent structures.

Given the discussion thus far, it will be appreciated that, in general terms, an exemplary apparatus includes a substrate 110; a processing unit (e.g., a high-heat-dissipating chip) 103 that is mounted to the substrate; an optical element 105 that is mounted to the substrate with the processing unit; and a heat spreader 100 that is attached to surfaces of the processing unit and of the optical element, opposite the substrate. The heat spreader includes: a first thermally anisotropic portion (e.g., graphite) 102 that is adjacent to the chip, with high-conductivity axes and a low-conductivity axis (high conductivity and low conductivity refer to thermal conductivity, and are relative to each other; i.e., the high-conductivity axes have a higher thermal conductivity than that along the low-conductivity axis). One of the high-conductivity axes being directed away from the chip. The heat spreader further includes: a second thermally anisotropic portion (e.g., graphite) 104 that is adjacent to the optical element, with high-conductivity axes and a low-conductivity axis, one of the high-conductivity axes being directed away from the optical element; and a connecting thermally anisotropic portion (e.g., graphite) 106 that is between the first and second thermally anisotropic portions, with high-conductivity axes and a low-conductivity axis, the low-conductivity axis being directed between the first and second thermally anisotropic portions. The connecting thermally anisotropic portion 106 effectively thermally isolates the first thermally anisotropic portion 102 from the second thermally anisotropic portion 104. “Thermally anisotropic,” as used herein, means that the thermal conductivity of the material is different along different axes; i.e., for x, y, and z axes, at least one of x, y, and z thermal conductivity is different than the other two (or all three can be different from each other).

In one or more embodiments, the optical element is a vertical-cavity surface-emitting laser. In one or more embodiments, each of the thermally anisotropic portions has a thermal conductivity along the high-conductivity axes that is at least 100 times a thermal conductivity along the low-conductivity axes. In some cases, each of the thermally anisotropic portions has a thermal conductivity along the high-conductivity axes that is about 10 times to about 300 times a thermal conductivity along the low-conductivity axes.

In one or more embodiments, the thermal conductivity along the low-conductivity axes is between 1 W/m-K and 10 W/m-K. In one or more embodiments, the thermal conductivity along the high-conductivity axes is between 500 W/m-K and 2000 W/m-K. In one or more embodiments, the thermal conductivity along the low-conductivity axes is about 6 W/m-K and the thermal conductivity along the high-conductivity axes is about 1500 W/m-K.

As noted, in one or more embodiments, the thermally anisotropic portions comprise graphite.

In some cases, the processing unit is configured to dissipate at least 4 times as much heat as the optical element when both are powered up.

In some such cases, the processing unit is configured to dissipate at least 25 W/m² when it is powered up.

The substrate can include, for example, a laminate structure. Generally, the substrate can include electrical and/or optical wiring and/or optical channels, respectively and a dielectric such as a laminate structure, a ceramic structure, a silicon structure, a glass structure or hybrid combination of these. The laminate structure could be a printed circuit board and/or a co-packaged optical (CPO) module; and the like.

According to another aspect, an exemplary heat spreader apparatus 100 includes a first portion 102; a second portion 104; and a connecting portion 106 between the first and second portions, with high-conductivity axes and a low-conductivity axis, the low-conductivity axis being directed between the first and second portions. The high-conductivity axes have a thermal conductivity about 10 times to about 300 times (in some cases, at least 100 times) the thermal conductivity of the low-conductivity axis. In one or more embodiments, the first, second, and connecting portions are blocks of graphite, and the apparatus forms a rectangular prism. In one or more embodiments, the high-conductivity axes have a thermal conductivity of about 1500 W/m-K and the low conductivity axes have a thermal conductivity of about 6 W/m-K.

According to another aspect, an exemplary apparatus 700 includes a substrate 110; one or more processing unit(s) and/or other electronic components 103 that is (are) mounted to the substrate; one or more optical elements (e.g., optical device(s), optical link(s) and/or optical component(s)) 105 that is(are) mounted to the substrate with the processing unit; and one or more heat spreader(s) 712 that is(are) attached to surfaces of the processing unit and of the optical element, opposite the substrate. The heat spreader(s) 712 includes: a backplane that defines first, second, and third slots 702, 704, 706; a first highly thermally conductive (e.g., as compared to the interposing block) block 708 that fits into the first slot adjacent to the processing unit; a second highly thermally conductive block 710 that fits into the second slot adjacent to the optical element; and an interposing block 707 that fits into the third slot between the chip and the optical element.

As noted, in one or more embodiments, the highly thermally conductive blocks comprise graphite. In one or more embodiments, the highly thermally conductive blocks have high-conductivity axes and low-conductivity axes, the thermal conductivity along the high-conductivity axes is about 1500 W/m-K, and the thermal conductivity along the low-conductivity axes is about 6 W/m-K.

The substrate can be, for example, a laminate structure, such as a printed circuit board. Generally, the substrate can include electrical and/or optical wiring and/or optical channels, respectively and a dielectric such as a laminate structure, a ceramic structure, a silicon structure, a glass structure or hybrid combination of these. The laminate structure could be a printed circuit board and/or a co-packaged optical (CPO) module; and the like.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. The term “about” is intended to convey, “within tolerances of a measurement procedure that is set forth in a technical standard that is accepted by those skilled in the art.”

What is claimed is:

1. An apparatus comprising:
a substrate;
a processing unit that is mounted to the substrate;
an optical element that is mounted to the substrate with the processing unit; and
a heat spreader that is attached to surfaces of the chip and of the optical element, opposite the substrate, wherein the heat spreader comprises:
a first thermally anisotropic portion adjacent to the chip, with high-conductivity axes and a low-conductivity axis, one of the high-conductivity axes being directed away from the chip;
a second thermally anisotropic portion adjacent to the optical element, with high-conductivity axes and a low-conductivity axis, one of the high-conductivity axes being directed away from the optical element; and
a connecting thermally anisotropic portion between the first and second thermally anisotropic portions, with high-conductivity axes and a low-conductivity axis, the low-conductivity axis being directed between the first and second thermally anisotropic portions.

2. The apparatus of claim 1, wherein the optical element is a vertical-cavity surface-emitting laser.

3. The apparatus of claim 1, wherein each of the thermally anisotropic portions has a thermal conductivity along the high-conductivity axes that is about 10 times to about 300 times a thermal conductivity along the low-conductivity axes.

4. The apparatus of claim 3, wherein the thermal conductivity along the low-conductivity axes is between 1 W/m-K and 10 W/m-K.

5. The apparatus of claim 4, wherein the thermal conductivity along the high-conductivity axes is between 500 W/m-K and 2000 W/m-K.

6. The apparatus of claim 3, wherein the thermal conductivity along the low-conductivity axes is about 6 W/m-K and the thermal conductivity along the high-conductivity axes is about 1500 W/m-K.

7. The apparatus of claim 1, wherein the thermally anisotropic portions comprise graphite.

8. The apparatus of claim 1, wherein the processing unit is configured to dissipate at least 4 times as much heat as the optical element when both are powered up.

9. The apparatus of claim 8, wherein the processing unit is configured to dissipate at least 25 W/m 2 when it is powered up.

10. The apparatus of claim 1, wherein the substrate comprises a laminate structure.

11. The apparatus of claim 10, wherein the substrate comprises a printed circuit board.

12. A heat spreader apparatus comprising:
a first portion;
a second portion; and
a connecting portion between the first and second portions, with high-conductivity axes and a low-conductivity axis, the low-conductivity axis being directed between the first and second portions, the high-conductivity axes having a thermal conductivity of about 10 times to about 300 times a thermal conductivity of the low-conductivity axis.

13. The apparatus of claim 12, wherein the first, second, and connecting portions are thermally anisotropic blocks, and the apparatus forms a rectangular prism.

14. The apparatus of claim 13, wherein the thermally anisotropic blocks comprise graphite.

15. The apparatus of claim 14, wherein the high-conductivity axes have a thermal conductivity of about 1500 W/m-K and the low conductivity axes have a thermal conductivity of about 6 W/m-K.

16. An apparatus comprising:
a substrate;
a processing unit that is mounted to the substrate;
an optical element that is mounted to the substrate with the processing unit; and
a heat spreader that is attached to surfaces of the chip and of the optical element, opposite the substrate, wherein the heat spreader comprises:
a backplane that defines first, second, and third slots;
a first highly thermally conductive block fit into the first slot adjacent to the chip;
a second highly thermally conductive block fit into the second slot adjacent to the optical element; and
an interposing block fit into the third slot between the chip and the optical element.

17. The apparatus of claim 16, wherein the highly thermally conductive blocks comprise graphite.

18. The apparatus of claim 17, wherein the highly thermally conductive blocks have high-conductivity axes and low-conductivity axes, wherein a thermal conductivity along the high-conductivity axes is about 1500 W/m-K and a thermal conductivity along the low-conductivity axes is about 6 W/m-K.

19. The apparatus of claim 16, wherein the highly thermally conductive blocks are thermally anisotropic and have high-conductivity axes and low-conductivity axes, wherein thermal conductivity along the high-conductivity axes is about 10 to about 300 times thermal conductivity along the low-conductivity axes.

20. The apparatus of claim 16, wherein the substrate comprises a laminate structure.
